(19) United States
(12) Patent Application Publication
(10) Pub. No.: US 2025/0042214 A1
(43) Pub. Date: Feb. 6, 2025

(54) DEVICE AND METHOD FOR DETECTING ABNORMALITY OF SOLENOID VALVE OF ELECTRONICALLY CONTROLLED SUSPENSION (ECS) SYSTEM, AND COMPUTER-READABLE STORAGE MEDIUM STORING PROGRAM FOR PERFORMING THE METHOD

(71) Applicant: HL MANDO CORPORATION, Gyeonggi-do (KR)

(72) Inventor: Gyuwon KIM, Gyeonggi-do (KR)

(21) Appl. No.: 18/789,678

(22) Filed: Jul. 31, 2024

(30) Foreign Application Priority Data
Jul. 31, 2023 (KR) 10-2023-0099321
Feb. 15, 2024 (KR) 10-2024-0021746

(51) Int. Cl. B60G 17/0185

(52) U.S. Cl. CPC B60G 17/0185; B60G 2400/102; B60G 2500/11; B60G 2600/1876; B60G 2600/1878

(57) ABSTRACT

Disclosed are a device and method for detecting an abnormality of a solenoid valve of an electronically controlled suspension (ECS) system, and a non-transitory computer-readable storage medium storing a program for performing the method. The device for detecting the abnormality of the solenoid valve of the ECS system is a device for detecting an abnormality of a solenoid valve of an ECS system, which detects an abnormality of a solenoid valve disposed in an ECS system of a vehicle, and includes a memory configured to store one or more instructions, and a processor configured to execute the one or more instructions, wherein the processor executes the one or more instructions to input input data representing a state of the ECS system into an artificial neural network model, obtain an estimated value of a physical quantity representing an output of the ECS system that is output by the artificial neural network model, compare the estimated value with a measurement value of the physical quantity, and detect the abnormality of the solenoid.

### CROSS-REFERENCE TO RELATED APPLICATION

This application claims priority to and the benefit of Korean Patent Application No. 10-2023-0099321, filed on Jul. 31, 2023, and Korean Patent Application No. 10-2024-0021746, filed on Feb. 15, 2024, the disclosures of which are incorporated herein by reference in its entirety.

### BACKGROUND

### 1. Technical Field

The present disclosure relates to a device and method for detecting an abnormality of a solenoid valve of an electronically controlled suspension (ECS) system, and a non-transitory computer-readable storage medium storing a program for performing the method, and more specifically, to a device and method for detecting an abnormality of a solenoid valve of an ECS system that is capable of detecting degradation in performance of a solenoid valve, which is an actuating element disposed in an ECS system of a vehicle to adjust a damping force, and a non-transitory computer-readable storage medium storing a program for performing the method.

### 2. Discussion of Related Art

An electronically controlled suspension (ECS) system automatically controls the suspension according to a condition of a road surface on which a vehicle is traveling, a driving condition of the vehicle, etc. The ECS system may ensure vehicle safety and ride comfort at the same time.

An ECS system includes a solenoid valve. The solenoid valve of the ECS system is an element that semi-actively drives an output (damping force) of the ECS system. When the solenoid valve of the ECS system fails, unpleasant riding comfort may be caused.

Therefore, in the case of the vehicle equipped with the ECS system, it is necessary to prognosticate a decrease in output of the solenoid valve disposed in the ECS system in advance rather than detecting a decrease in output of the solenoid valve after the fact in order to maintain safety and ride comfort. However, conventional approaches related to the fail-safety of solenoid valves of ECS systems focus on follow-up measures after failure rather than preventing failure in advance. Further, the conventional ECS systems use the fail-safety based on the current of solenoid valves, but have a limitation that the fail safety is insufficient in terms of direct response to a decrease in output.

(Patent Document) Korean Patent Registration No. 2429549 “ELECTRONIC CONTROL SUSPENSION APPARATUS AND METHOD FOR CONTROLLING DAMPING FORCE THEREOF,” registered on Aug. 1, 2022

### SUMMARY OF THE INVENTION

The present disclosure is directed to providing a device and method for detecting an abnormality of a solenoid valve of an electronically controlled suspension (ECS) system that is capable of prognosticating degradation in performance of a solenoid valve that is disposed in an ECS system of a vehicle to adjust an output of the ECS system, and a non-transitory computer-readable storage medium storing a program for performing the method.

The present disclosure is directed to providing a device and method for detecting an abnormality of a solenoid valve of an ECS system that is capable of efficiently detecting in advance a decrease in output of a solenoid valve of an ECS system using signals of a controller area network (CAN) in a vehicle, and a non-transitory computer-readable storage medium storing a program for performing the method.

The objects of the present disclosure are not limited to the above-described objects, and other objects that are not mentioned will be able to be clearly understood by those skilled in the art to which the present disclosure pertains from the following description.

According to an aspect of the present disclosure, there is provided a device for detecting an abnormality of a solenoid valve of an ECS system, which detects an abnormality of a solenoid valve disposed in an ECS system of a vehicle, which includes a memory configured to store one or more instructions, and a processor configured to execute the one or more instructions, wherein the processor executes the one or more instructions to input input data representing a state of the ECS system into an artificial neural network model, obtain an estimated value of a physical quantity representing an output of the ECS system that is output by the artificial neural network model, compare the estimated value with a measurement value of the physical quantity, and detect the abnormality of the solenoid valve.

The input data may consist of signals that are obtainable through a CAN of the vehicle. The physical quantity may be a damping force of the ECS system.

The input data may include a vertical acceleration of wheels of the vehicle and a vertical acceleration of a body of the vehicle.

The input data may further include at least one of a wheel speed of the vehicle, a steering angle of the vehicle, a steering angular velocity of the vehicle, a displacement of an accelerator pedal of the vehicle, a displacement of a brake pedal of the vehicle, and a lateral acceleration of the vehicle.

The artificial neural network model may include a generative adversarial network (GAN) including a generator that receives the input data and generates the estimated value.

The artificial neural network model may further include a discriminator that receives measurement data including the input data and the measurement value and outputs a discrimination value for the measurement data.

The generator may be composed of a multivariate transformer.

The processor may execute the one or more instructions to input error data related to a difference between the estimated value and the measurement value into an abnormality detection model and determine whether the solenoid valve is abnormal.

The abnormality detection model may use a one-class support vector machine (OCSVM) algorithm.

There may be a plurality of data sets including the input data, the measurement value, and the estimated value, and the error data may include a mean and standard deviation of errors between the measurement value and the estimated value that are obtained from each of the plurality of data sets, a maximum absolute error between the measurement value and the estimated value of the plurality of data sets, and the discrimination value of the discriminator for the measurement data of the plurality of data sets.

The discriminator may additionally receive estimate data including the input data and the estimated value and additionally output a discrimination value for the estimate data.

The artificial neural network model may be constructed by the generator and the discriminator alternately performing learning, and the input data and the measurement value that are used during the learning may be obtained when the vehicle and the solenoid valve are in a normal state.

The estimated value may follow the measurement value of the physical quantity obtained when the vehicle and the solenoid valve are in a normal state.

According to another aspect of the present disclosure, there is provided a method of detecting an abnormality of a solenoid valve of an ECS system, in which an abnormality of a solenoid valve disposed in an ECS system of a vehicle is detected, which includes inputting, by a processor, input data representing a state of the ECS system into an artificial neural network model and obtaining an estimated value of a physical quantity representing an output of the ECS system that is output by the artificial neural network model, and comparing, by the processor, the estimated value with a measurement value of the physical quantity and detecting the abnormality of the solenoid valve.

The physical quantity may be a damping force of the ECS system.

The input data may include a vertical acceleration of wheels of the vehicle and a vertical acceleration of a body of the vehicle.

The input data may further include at least one of a wheel speed of the vehicle, a steering angle of the vehicle, a steering angular velocity of the vehicle, a displacement of an accelerator pedal of the vehicle, a displacement of a brake pedal of the vehicle, and a lateral acceleration of the vehicle.

The artificial neural network model may be a GAN including a generator that receives the input data and generates the estimated value, and a discriminator that receives measurement data including the input data and the measurement value and outputs a discrimination value for the measurement data.

In the obtaining of the estimated value of the physical quantity, the processor may input the input data into the generator and obtain the estimated value generated by the generator.

The detecting of the abnormality of the solenoid valve may include inputting, by the processor, measurement data including the input data and the measurement value of the physical quantity into the discriminator and obtaining a discrimination value for the measurement data generated by the discriminator, and inputting, by the processor, error data including the discrimination value for the measurement data and numerical values related to a difference between the estimated value and the measurement value into an abnormality detection model and obtaining an output of the abnormality detection model.

There may be a plurality of data sets including the input data, the measurement value, and the estimated value, and the error data may include a mean and standard deviation of errors between the measurement value and the estimated value that are obtained from each of the plurality of data sets, a maximum absolute error between the measurement value and the estimated value of the plurality of data sets, and the discrimination value of the discriminator for the measurement data of the plurality of data sets.

The artificial neural network model may be constructed by the generator and the discriminator alternately performing learning, and the input data and the measurement value that are used during the learning may be obtained when the vehicle and the solenoid valve are in a normal state.

According to still another aspect of the present disclosure, there is provided a non-transitory computer-readable storage medium in which a program including at least one instruction for performing the method of detecting the abnormality of the solenoid valve of the ECS system is stored.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram schematically illustrating a configuration of an electronically controlled suspension (ECS) system of a vehicle;

FIG. 2 is a diagram illustrating a configuration of a device for detecting an abnormality of a solenoid valve of an ECS system according to an embodiment of the present disclosure;

FIG. 3 is a diagram illustrating models that are used to obtain an estimated value or detect an abnormality in the device for detecting the abnormality of the solenoid valve of the ECS system according to an embodiment of the present disclosure;

FIG. 4 is a diagram illustrating a detailed configuration of an artificial neural network model;

FIG. 5 is a diagram illustrating a detailed configuration of a generator of the artificial neural network model;

FIG. 6 is a diagram illustrating the operation of the device for detecting the abnormality of the solenoid valve of the ECS system according to an embodiment of the present disclosure;

FIG. 7 is a flowchart of a method of detecting an abnormality of a solenoid valve of an ECS system according to an embodiment of the present disclosure; and

FIG. 8 is a detailed flowchart of an operation of detecting the abnormality of the solenoid valve in the method of detecting the abnormality of the solenoid valve of the ECS system according to an embodiment of the present disclosure.

### DETAILED DESCRIPTION OF EXEMPLARY EMBODIMENTS

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their invention.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

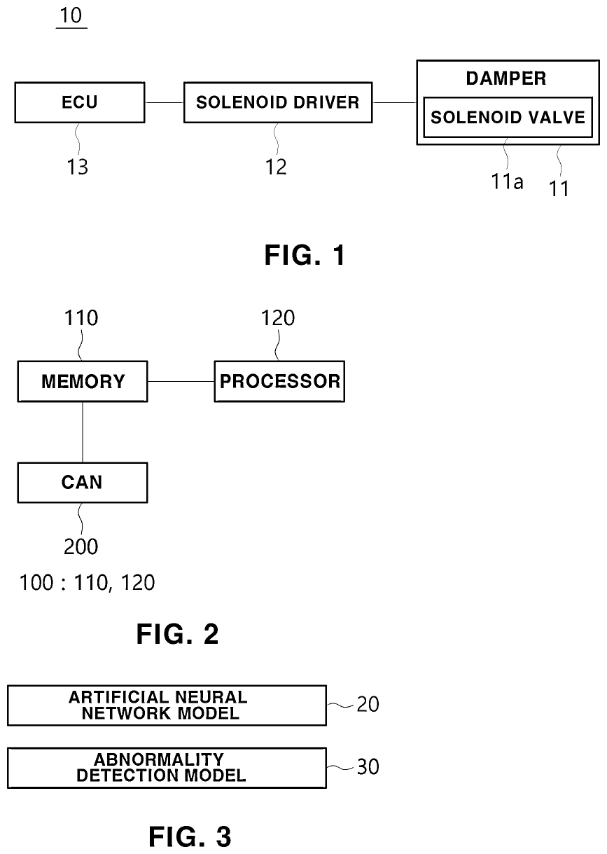

FIG. 1 is a diagram schematically illustrating a configuration of an electronically controlled suspension (ECS) system of a vehicle.

An ECS system 10 of the vehicle is installed in the vehicle and actively controls a suspension device according to road surface conditions and driving conditions. The ECS system 10 may change a height of a body of the vehicle according to the road surface conditions and the driving conditions to ensure driving safety and ride comfort at the same time.

Referring to FIG. 1, the ECS system 10 may include a damper 11 having a solenoid valve 11a, a solenoid driver 12 that drives a solenoid of the solenoid valve 11a, and an electronic control unit (ECU) 13 that controls the solenoid driver 12.

FIG. 2 is a diagram illustrating a configuration of a device for detecting an abnormality of a solenoid valve of an ECS system according to an embodiment of the present disclosure. Further, FIG. 3 is a diagram illustrating models that are used to obtain an estimated value or detect an abnormality in the device for detecting the abnormality of the solenoid valve of the ECS system according to an embodiment of the present disclosure.

A device 100 for detecting the abnormality of the solenoid valve of the ECS system according to the embodiment of the present disclosure detects an abnormality of the solenoid valve 11a disposed in the ECS system of the vehicle. More specifically, the device 100 for detecting the abnormality of the solenoid valve of the ECS system may detect an abnormality of a solenoid valve that is disposed in the ECS system of the vehicle to adjust a damping force.

The device 100 for detecting the abnormality of the solenoid valve of the ECS system according to the embodiment of the present disclosure may prognosticate degradation in the function of the solenoid valve before a failure of the solenoid valve occurs using a digital twin algorithm for a vehicle based on artificial intelligence. The digital twin algorithm may virtually build the ECS system of the vehicle.

Referring to FIG. 2, the device 100 for detecting the abnormality of the solenoid valve of the ECS system according to the embodiment of the present disclosure may include a memory 110 and a processor 120.

The memory 110 stores one or more instructions. The one or more instructions may be executed by the processor 120.

The memory 110 may include a hardware device configured to store and execute program instructions. For example, the memory 110 may include a storage medium, such as a read-only memory (ROM), a random access memory (RAM), a flash memory, etc. Further, the memory 110 may include a magnetic medium such as a floppy disk or a magnetic tape, an optical medium such as a compact disc read only memory (CD-ROM) or a digital video disc (DVD), a magneto-optical medium such as a floptical disk, etc.

The processor 120 executes the one or more instructions. For example, the processor 120 may be a hardware unit that performs calculations and control within a computer. The processor 120 may include at least one arithmetic logic unit (ALU) and a register.

The processor 120 may execute the one or more instructions to input input data representing a state of the ECS system 10 into an artificial neural network model 20 and obtain an estimated value of a physical quantity representing an output of the ECS system that is output by the artificial neural network model 20.

In one embodiment of the present disclosure, the input data may include a vertical acceleration of wheels of the vehicle and a vertical acceleration of a body of the vehicle. Further, the input data may further include a wheel speed of the vehicle, a steering angle of the vehicle, a steering angular velocity of the vehicle, a displacement of an accelerator pedal of the vehicle, a displacement of a brake pedal of the vehicle, and a lateral acceleration of the vehicle.

The physical quantity may be a damping force of the ECS system 10. That is, the artificial neural network model 20 may output an estimated value of the damping force. The damping force of the ECS system may be determined according to the operation of the solenoid valve 11a.

Meanwhile, the input data may consist of signals that can be obtained through a controller area network (CAN) 200 of the vehicle. The examples of the input data described above are data that can be obtained through a CAN of a typical vehicle. Accordingly, according to the present disclosure, there is no need to use an additional sensor in relation to detecting the abnormality of the solenoid valve.

In this regard, the memory 110 may be directly or indirectly connected to the CAN 200 of the vehicle. The memory 110 may receive input data from the CAN 200. Accordingly, the processor 120 may obtain the input data from the memory 110.

The artificial neural network model 20 receives the input data and outputs the estimated value of the physical quantity. In one embodiment of the present disclosure, the artificial neural network model 20 may include a generative adversarial network (GAN).

In one embodiment of the present disclosure, the artificial neural network model 20 may be a deep learning-based neural twin model for the ECS system of the vehicle. In other words, the artificial neural network model 20 may serve as a virtual twin model of the ECS system of the vehicle.

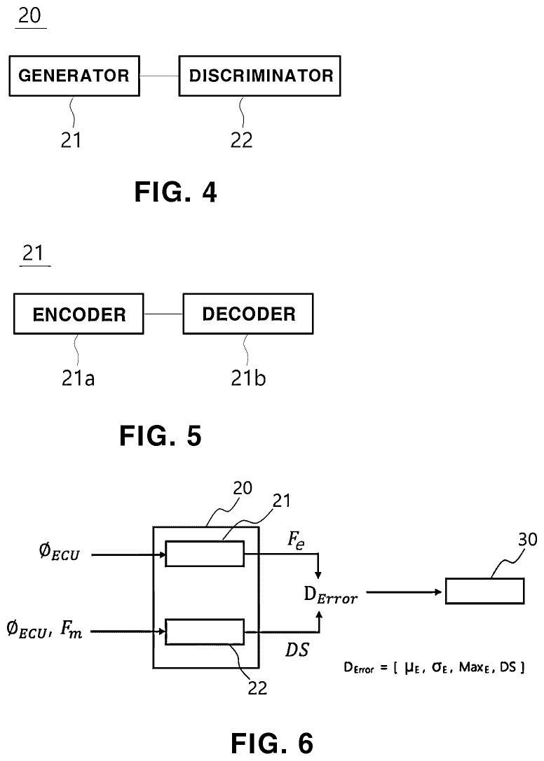

FIG. 4 is a diagram illustrating a detailed configuration of the artificial neural network model.

Referring to FIG. 4, the artificial neural network model 20 may include a generator 21 and a discriminator 22.

The artificial neural network model 20 is constructed by the generator 21 and the discriminator 22 alternately performing learning, and data used during the learning may be obtained when the vehicle and the solenoid valve are in a normal state. Accordingly, the estimated value may follow a measurement value of the physical quantity obtained when the vehicle and the solenoid valve are in a normal state.

The generator 21 receives the input data and generates the estimated value. The generator 21 may include a neural network. The generator 21 may be composed of a multivariate transformer. That is, the artificial neural network model 20 may be a GAN based on a multivariate transformer.

In one embodiment of the present disclosure, the generator 21 may receive the vertical acceleration of the wheels of the vehicle, the vertical acceleration of the body of the vehicle, the wheel speed of the vehicle, the steering angle of the vehicle, the steering angular velocity of the vehicle, the displacement of the accelerator pedal of the vehicle, the displacement of the brake pedal of the vehicle, and the lateral acceleration of the vehicle as the input data.

The generator 21 may calculate the input data and output an estimated value of the damping force of the ECS system. The estimated value estimated by the generator 21 follows the measurement value of the damping force that is output corresponding to the input data when the ECS system is in a normal state.

FIG. 5 is a diagram illustrating a detailed configuration of the generator of the artificial neural network model.

Referring to FIG. 5, the generator 21 may include an encoder 21a and a decoder 21b.

The encoder 21a and the decoder 21b form a network for estimating the damping force of the ECS system. In other words, the generator 21 may be composed of an encoder 21a-decoder 21b structured network trained in an end-to-end manner to estimate the damping force.

The encoder 21a may be designed to extract high-level features from input data using a transformer block and linear operation. In this case, the transformer block may include an embedding layer, a self-attention layer, and a feed-forward layer.

First, the embedding layer in the transformer block may encode spatiotemporal information into input sequences using a trainable embedding matrix.

Next, deep features may be extracted through the self-attention layer, and refinement may be performed using the feed-forward layer.

In this case, the self-attention layer may utilize a scaled dot-product attention mechanism. The self-attention layer may be a key component in transformer-based deep neural network (DNN) architectures, allowing the model to process and understand dependencies within the input sequence.

Scaled dot-product attention may first apply layer normalization to the input sequence and process results of the layer normalization into three unique vectors: a query (Q); a key (K); and a value (V) through linear operations.

Next, an attention score AS may be calculated for each position in the input sequence on the basis of the derived vectors. A calculation formula for the attention score AS may be given as Formula 1 below.

$$AS = σ ( \frac{Q \cdot K}{\sqrt{{‖ {x}_{input} ‖}_{dim}}} ) \cdot V \qquad ( Formula 1 )$$

(σ( ) denotes a softmax operation, |xᵢₙₚᵤₜ|_{dim} denotes a feature dimension of an input, and · denotes a dot product.)

An attention score quantifies the relative importance of each position in the input sequence relevant to a given query. That is, higher scores are assigned to more appropriate positions.

An output of the transformer block may be fed to two different linear operations to calculate a query, a key vector, and an initial input value of the decoder 21b.

The decoder 21b may estimate the damping force of the ECS system using the obtained values in an auto-regressive manner similar to sequence-to-sequence recurrent neural networks.

Like the encoder 21a, the decoder 21b may include a transformer block and linear operations. Additionally, the decoder 21b may include a cross-attention layer within the transformer block.

The cross-attention layer may perform scaled dot-product attention using the query and key vector of the encoder 21a to learn a dynamic correlation between input signals and estimated signals.

The discriminator 22 receives measurement data including the input data and the measurement value and outputs a discrimination value for the measurement data.

The discriminator 22 is a classifier that aims to determine the conditional probability. The discriminator 22 determines the probability of an example being real or fake given that set of input features. The discrimination value from the discriminator 22 are classification labels. For example, the discrimination value from the discriminator 22 is 0 or 1.

Meanwhile, the discriminator 22 may additionally receive estimate data including the input data and the estimated value and additionally output a discrimination value for the estimate data. Such a process may be accomplished when the generator 21 and the discriminator 22 perform learning.

In this way, the discriminator 22 may output the discrimination value for the measurement data during an operation process for abnormality detection, while the discriminator 22 may output the discrimination value for the estimate data during an operation process for learning.

The discriminator 22 may be composed of a discriminator network used for adversarial training of a GAN. In other words, the generator 21 and the discriminator 22 may be trained using an adversarial training method to improve estimation performance and establish a GAN model.

More specifically, the discriminator 22 may perform optimization alternately with the generator 21 to solve a Wasserstein min-max problem such as Formula 2.

$${min}_{G} {max}_{D} {E}_{{x}_{D , Real}} [ D ( {x}_{D , Real} ) ] - {E}_{{x}_{D , Fake}} [ D ( {x}_{D , Fake} ) ] \qquad ( Formula 2 )$$

(x_{D,Real} denotes a real data set consisting of the input data and the measurement value of the damping force of the ECS system, and x_{D,Fake} denotes a virtual data sample consisting of the input data and the estimated value of the damping force of the ECS system.)

In the artificial neural network model 20, the generator 21 is trained to deceive the discriminator 22, which distinguishes the spatiotemporal characteristics of x_{D,Real} and x_{D,Fake}. Accordingly, the generator 21 may generate the estimated value for following the damping force of the ECS system of the vehicle in a normal state.

In this regard, a loss function for GAN training may be defined as Formula 3 below.

$${L}_{G} = \frac{1}{N} \sum \vert {y}_{G} - {\hat{y}}_{G} \vert + 0.001 \times \frac{1}{N} \sum [ - D ( {x}_{D , Fake} ) ] , \qquad ( Formula 3 )$$

$${L}_{D} = \frac{1}{N} \sum [ D ( {x}_{D , Fake} ) - D ( {x}_{D , Real} ) ] + 10 \times \frac{1}{N} \sum [ {( {‖ {∇}_{{x}_{D , Fake}} D ( {x}_{D , Fake} ) ‖}_{2} - 1 )}^{2} ]$$

(N denotes a size of a batch, LG denotes a loss function of the generator, and LD denotes a loss function of the discriminator.)

The first term of a loss of the generator 21 corresponds to a loss L_{MAE} of a mean absolute error of supervised training. The remaining term of the loss of the generator 21 together with a loss of the discriminator 22 constitute a loss function L_{GAN} of the GAN.

In one embodiment of the present disclosure, in order to reflect the dynamic characteristics of the ECS system to the loss function, a damping force function derived from a quarter car model may be considered. The quarter car model is generally used in passenger car design and is a suspension model to consider an input from one wheel of the vehicle.

The quarter car model may be defined as Formula 4 below.

$${m}_{b} {\ddot{x}}_{b} + c ( {\dot{x}}_{b} - {\dot{x}}_{w} ) + {k}_{s} ( {x}_{b} - {x}_{w} ) = 0 \qquad ( Formula 4 )$$

(m_{b} denotes a mass of the body, \ddot{x}_{b} denotes the vertical acceleration of the body of the vehicle, \dot{x}_{b} denotes a vertical velocity of the body of the vehicle, \dot{x}_{w} denotes a vertical velocity of the wheels of the vehicle, (x_{b}−x_{w}) denotes a displacement between the body and the wheels of the vehicle, and kₛ denotes a given elastic coefficient.)

From such a quarter car model, the damping force of the ECS system of the vehicle may be derived as Formula 5.

$${F}_{c} = c ( {\dot{x}}_{b} - {\dot{x}}_{w} ) = - {m}_{b} {\ddot{x}}_{b} - {k}_{s} ( {x}_{b} - {x}_{w} ) \qquad ( Formula 5 )$$

(\dot{x}_{b} denotes the vertical velocity of the body of the vehicle, \dot{x}_{w} denotes the vertical velocity of the wheels of the vehicle, m_{b} denotes the mass of the body, \ddot{x}_{b} denotes the vertical acceleration of the body of the vehicle, kₛ denotes the given elastic coefficient, and (x_{b}−x_{w}) denotes the displacement between the body and the wheels of the vehicle.)

In this case, the damping force corrected by reflecting the uncertainty of the model and system may be derived as Formula 6 below.

$${F}_{e} = f ( {∅}_{ECU} ) = - ( {m}_{b} + {δ}_{1} ) {\ddot{x}}_{b} - ( {k}_{s} + {δ}_{2} ) ( {x}_{b} - {x}_{w} ) + {δ}_{3} \qquad ( Formula 6 )$$

Ø_{ECU} denotes the input data, m_{b} denotes the mass of the body, \ddot{x}_{b} denotes the vertical acceleration of the body of the vehicle, (x_{b}−x_{w}) denotes the displacement between the body and the wheels of the vehicle, and kₛ denotes the given elastic coefficient.

The corrected damping force Fₑ becomes the estimated value of the damping force of the ECS system. Further, in Formula 6, δ₁ and δ₂ denote the model-related uncertainty, and δ₃ denotes the uncertainty of the system. Meanwhile, the input data Ø_{ECU} is something that the ECU of the vehicle can receive or measure through the CAN.

The processor 120 detects an abnormality of the solenoid valve by comparing the estimated value with the measurement value of the physical quantity. The processor 120 may execute the one or more instructions to input error data related to a difference between the estimated value and the measurement value into an abnormality detection model 30 and determine whether the solenoid valve is abnormal. For example, the abnormality detection model 30 may use a one-class support vector machine (OCSVM) algorithm.

There may be a plurality of data sets including the input data, the measurement value, and the estimated value. The error data may include a mean and standard deviation of errors between the measurement value and the estimated value that are obtained from each of the plurality of data sets, a maximum absolute error between the measurement value and the estimated value of the plurality of data sets, and the discrimination value of the discriminator for measurement data of the plurality of data sets.

More specifically, the plurality of data sets including the measurement value and the estimated value may be treated as one batch. For example, 100 to 150 data sets (as a specific example, 128 data sets) may be treated as one batch, and the error data may be obtained for each batch.

The error data obtained for one batch may be input to the abnormality detection model 30. Further, the level of the abnormality of the solenoid valve (degradation in performance of the solenoid valve) may be detected based on an output (characteristic) obtained from the abnormality detection model 30 that receives the error data.

Regarding an anomaly detection metric, an F1 score given as Formula 7 below may be considered.

$$F 1 = \frac{2 \times TP}{2 \times TP + FP + FN} \qquad ( Formula 7 )$$

(TP denotes true positive, FP denotes false positive, and FN denotes false negative, wherein positive indicates degradation in performance of the solenoid valve.)

Meanwhile, as described above, the discriminator 22 may calculate not only the discrimination value for the measurement data included in the data set, but also the discrimination value for the estimate data included in the data set. The discrimination value of the discriminator 22 for the estimate data of the data set may be provided as feedback to the generator 21 of the artificial neural network model 20 and used for training.

Until now, the configuration of the device 100 for detecting the abnormality of the solenoid valve of the ECS system according to the embodiment of the present disclosure has been described in detail. Hereinafter, the operation of the device 100 for detecting the abnormality of the solenoid valve of the ECS system will be described in detail.

FIG. 6 is a diagram illustrating the operation of the device for detecting the abnormality of the solenoid valve of the ECS system according to an embodiment of the present disclosure.

Referring to FIG. 6, the device 100 for detecting the abnormality of the solenoid valve of the ECS system according to the embodiment of the present disclosure may operate as follows.

First, the memory 110 stores input data Ø_{ECU} obtained from the ECS system of the vehicle and a measurement value Fₘ of the damping force of the ECS system.

As described above, the input data Ø_{ECU} may include a vertical acceleration of the wheels of the vehicle, a vertical acceleration of the body of the vehicle, a wheel speed of the vehicle, a steering angle of the vehicle, a steering angular velocity of the vehicle, a displacement of the accelerator pedal of the vehicle, a displacement of the brake pedal of the vehicle, and a lateral acceleration of the vehicle.

Meanwhile, a plurality of pieces of input data Ø_{ECU} and a plurality of measurement values Fₘ of the damping force of the ECS system may be treated as one batch. That is, in one embodiment of the present disclosure, data processing and calculations may be performed in units of data batches.

Next, the processor 120 may execute one or more instructions to input the input data Ø_{ECU} into the artificial neural network model 20 and obtain an estimated value Fₑ of the damping force of the ECS system output by the artificial neural network model 20. More specifically, the processor 120 may input the input data Grow into the generator 21 of the artificial neural network model 20 and obtain an estimated value F of the damping force of the ECS system output by the generator 21.

Further, the processor 120 may execute the one or more instructions to input the input data Ø_{ECU} and the measurement value Fₘ of the damping force into the artificial neural network model 20 and obtain a discrimination value DS. More specifically, the processor 120 may input measurement data including the input data Ø_{ECU} and the measurement value Fₘ of the damping force into the discriminator 22 of the artificial neural network model 20 and obtain the discrimination value DS output by the discriminator 22 for the measurement data.

Next, the processor 120 outputs error data D_{Error}. The error data D_{Error} may be output for each data batch.

As described above, there are the plurality of data sets including the input data, the measurement value, and the estimated value, and the error data D_{Error} may include a mean μ_{E} and a standard deviation σ_{E} of errors between the measurement value and the estimated value that are obtained from each of the plurality of data sets, a maximum absolute error^{MaxE} between the measurement value and the estimated value of the plurality of data sets, and the discrimination value DS of the discriminator 22 for the measurement data obtained from the plurality of data sets.

Lastly, the processor 120 may execute the one or more instructions to input the error data D_{Error} into the abnormality detection model 30 and obtain an output of the abnormality detection model 30. As described above, the abnormality detection model 30 may include an OCSVM algorithm.

Based on the output obtained from the abnormality detection model 30 that receives the error data D_{Error}, the processor 120 may detect the level of the abnormality (degradation in performance of the solenoid valve) of the solenoid valve of the ECS system.

As described above, the device 100 for detecting the abnormality of the solenoid valve of the ECS system according to the embodiment of the present disclosure has been described in detail. Hereinafter, a method of detecting the abnormality of the solenoid valve of the ECS system will be described.

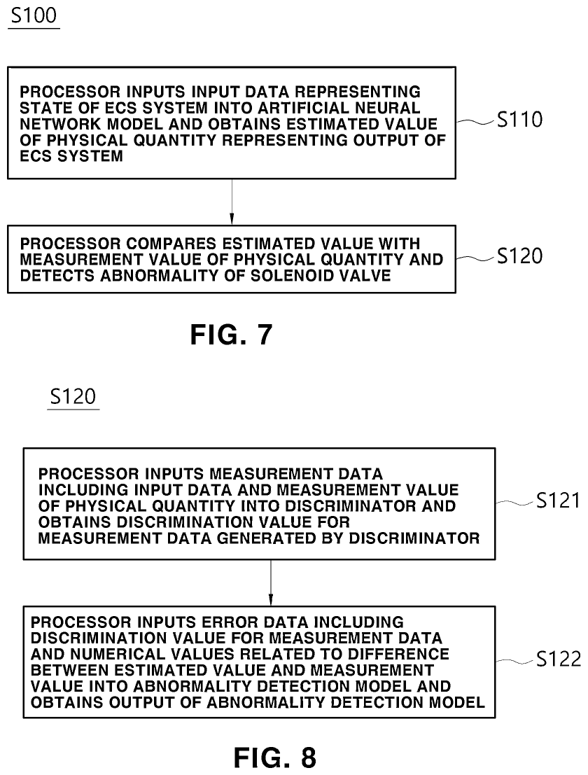

FIG. 7 is a flowchart of a method of detecting an abnormality of a solenoid valve of an ECS system according to an embodiment of the present disclosure.

In a method S100 of detecting the abnormality of the solenoid valve of the ECS system according to the embodiment of the present disclosure, an abnormality of the solenoid valve 11a disposed in the ECS system of the vehicle is detected. More specifically, in the method S100 of detecting the abnormality of the solenoid valve of the ECS system, an abnormality of a solenoid valve that is disposed in the ECS system of the vehicle to adjust a damping force may be detected.

Referring to FIG. 7, the method S100 of detecting the abnormality of the solenoid valve of the ECS system according to the embodiment of the present disclosure may be performed as follows.

First, the processor 120 may input input data representing a state of the ECS system into the artificial neural network model 20 and obtain an estimated value of a physical quantity representing an output of the ECS system that is output by the artificial neural network model 20 (S110).

The input data may include a vertical acceleration of wheels of the vehicle and a vertical acceleration of a body of the vehicle. Further, the input data may further include at least one of a wheel speed of the vehicle, a steering angle of the vehicle, a steering angular velocity of the vehicle, a displacement of an accelerator pedal of the vehicle, a displacement of a brake pedal of the vehicle, and a lateral acceleration of the vehicle.

The physical quantity may be a damping force of the ECS system. The damping force of the ECS system may be determined according to the operation of the solenoid valve.

For example, the input data may be composed of the vertical acceleration of the wheels of the vehicle, the vertical acceleration of the body of the vehicle, the wheel speed of the vehicle, the steering angle of the vehicle, the steering angular velocity of the vehicle, the displacement of the accelerator pedal of the vehicle, the displacement of the brake pedal of the vehicle, and the lateral acceleration of the vehicle.

In one embodiment of the present disclosure, the artificial neural network model 20 may include a GAN. In other words, the artificial neural network model 20 may be a deep learning-based neural twin model for the ECS system of the vehicle.

The artificial neural network model 20 may include the generator 21 and the discriminator 22. The generator 21 receives the input data and generates the estimated value. The generator 21 may be composed of a multivariate transformer. Further, the discriminator 22 receives measurement data including the input data and the measurement value and outputs a discrimination value for the measurement data.

In operation S110 of obtaining the estimated value of the physical quantity, the processor 120 may input the input data into the generator 21 and obtain the estimated value generated by the generator 21.

Meanwhile, the artificial neural network model 20 is constructed by the generator 21 and the discriminator 22 performing learning, and the input data and the measurement value used during the learning may be obtained when the vehicle and the solenoid valve are in a normal state. Accordingly, the estimated value may follow the measurement value of the physical quantity obtained when the vehicle and the solenoid valve are in a normal state.

Next, the processor 120 compares the estimated value with the measurement value of the physical quantity to detect an abnormality of the solenoid valve (S120).

The processor 120 may execute the one or more instructions to input error data related to a difference between the estimated value and the measurement value into the abnormality detection model 30 and determine whether the solenoid valve is abnormal. For example, the abnormality detection model 30 may use an OCSVM algorithm.

FIG. 8 is a detailed flowchart of an operation of detecting an abnormality of a solenoid valve in the method of detecting the abnormality of the solenoid valve of the ECS system according to an embodiment of the present disclosure.

Referring to FIG. 8, the operation S120 of detecting the abnormality of the solenoid valve may be performed as follows.

First, the processor 120 may input measurement data including the input data and the measurement value of the physical quantity into the discriminator 22 and obtain a discrimination value for the measurement data generated by the discriminator 22 (S121).

Next, the processor 120 may input error data including a discrimination value for the measurement data and numerical values related to the difference between the estimated value and the measurement value into the abnormality detection model 30 and obtain an output of the abnormality detection model 30 (S122).

There may be a plurality of data sets including the input data, the measurement value, and the estimated value. The error data may include a mean and standard deviation of errors between the measurement value and the estimated value that are obtained from each of the plurality of data sets, a maximum absolute error between the measurement value and the estimated value of the plurality of data sets, and the discrimination value of the discriminator for measurement data of the plurality of data sets.

More specifically, the plurality of data sets including the measurement value and the estimated value may be treated as one batch. For example, 100 to 150 data sets (as a specific example, 128 data sets) may be treated as one batch, and the error data may be obtained for each batch.

The error data obtained for one batch may be input to the abnormality detection model 30. Further, the level of the abnormality (degradation in performance of the solenoid valve) of the solenoid valve may be detected based on an output (characteristic) obtained from the abnormality detection model 30 that receives the error data.

Regarding the anomaly detection metric, the F1 score given as Formula 7 as described above may be considered.

Meanwhile, the present disclosure additionally provides a non-transitory computer-readable storage medium storing a program for performing the method of detecting the abnormality of the solenoid valve of the ECS system. Specifically, the present disclosure may provide a non-transitory computer-readable storage medium in which a program including at least one instruction for performing the method of detecting the abnormality of the solenoid valve of the ECS system is stored.

In this case, the instruction may include not only machine code generated by a compiler but also high-level language code executable by a computer.

The non-transitory computer-readable storage medium may include a magnetic medium such as a hard disk, a floppy disk, or a magnetic tape, an optical medium such as a CD-ROM or a DVD, a magneto-optical medium such as a floptical disk, or a hardware device configured to store and execute program instructions, such as a ROM, a RAM, a flash memory, etc.

As a result of a simulation, it was found that according to the present disclosure, a decrease up to 10% of a maximum output of the damping force of the ECS system can be predicted with the performance of an F1 score of 0.85 or higher. In other words, according to the present disclosure, the level of degradation of the solenoid valve can be accurately predicted before the solenoid valve disposed in the ECS system of the vehicle completely fails.

According to the present disclosure, it is possible to predict an abnormality of the solenoid valve of the ECS system in advance before a failure of the solenoid valve of the ECS system occurs. As a result, it is possible to take proactive measures before a failure of the solenoid valve occurs and it is possible to prevent the failure of the solenoid valve.

In this way, the present disclosure provides the estimation of the future operation and remaining useful life of the system and the prognostic diagnosis suitable for predictive maintenance applications. Accordingly, proactive measures and maintenance can be effectively guided before a failure of the solenoid valve of the ECS system of the vehicle occurs.

According to the above configuration, in the device and method for detecting the abnormality of the solenoid valve of the ECS system, and the non-transitory computer-readable storage medium storing a program for performing the method according to an aspect of the present disclosure, it is possible to prognosticate degradation in performance of the solenoid valve before a failure of the solenoid valve disposed in the ECS system occurs based on an artificial intelligence-based digital twin algorithm.

Further, in the device and method for detecting the abnormality of the solenoid valve of the ECS system, and the non-transitory computer-readable storage medium storing a program for performing the method according to an aspect of the present disclosure, it is possible to predict degradation in performance of the solenoid valve of the ECS system using signals of a CAN of the vehicle without a separate additional sensor.

It should be understood that the effects of the present disclosure are not limited to the above-described effects, and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A device comprising:
a memory configured to store one or more instructions; and
a processor configured to execute the one or more instructions comprising:
inputting input data representing a state of an electronically controlled suspension (ECS) system into an artificial neural network model,
obtaining at least one estimated value of a physical quantity representing an output of the ECS system from the artificial neural network model,
detecting abnormality of a solenoid valve included in the ECS system of a vehicle by comparing the at least one estimated value of the physical quantity obtained from the artificial neural network model with at least one measured value of the physical quantity measured by one or more sensors.

2. The device of claim 1, wherein the input data comprises one or more signals obtained through a controller area network (CAN) of the vehicle.

3. The device of claim 1, wherein the physical quantity includes a damping force of the ECS system.

4. The device of claim 1, wherein the input data includes a vertical acceleration of a wheel of the vehicle and a vertical acceleration of a body of the vehicle.

5. The device of claim 4, wherein the input data further includes at least one of a speed of the wheel of the vehicle, a steering angle of the vehicle, a steering angular velocity of the vehicle, a displacement of an accelerator pedal of the vehicle, a displacement of a brake pedal of the vehicle, and a lateral acceleration of the vehicle.

6. The device of claim 1, wherein the artificial neural network model includes a generative adversarial network (GAN) including a generator configured to receive the input data representing the state of the ESC system and generate the estimated value based on the received input data.

7. The device of claim 6, wherein the artificial neural network model further includes a discriminator configured to receive measurement data including the input data representing the state of the ESC system and the measured value of the physical quantity measured by the one or more sensors and output a discrimination value for the measurement data.

8. The device of claim 7, wherein the processor is configured to input error data related to a difference between the estimated value of the physical quantity obtained from the artificial neural network model and the measured value of the physical quantity measured by the one or more sensors into an abnormality detection model to determine whether the solenoid valve included in the ECS system is abnormal.

9. The device of claim 8, wherein:
the at least one measured value measured by the one or more sensors comprises a plurality of measured values, the at least one estimated value obtained from the artificial neural network model comprises a plurality of obtained values, and a plurality of data sets include the input data, the plurality of measured values, and the plurality of estimated values, and
the error data includes a mean and standard deviation of errors between the plurality of measured values and the plurality of estimated values that are obtained from the plurality of data sets, a maximum absolute error among the errors between the plurality of measured values and the plurality of estimated values of the plurality of data sets, and the discrimination value of the discriminator for the measurement data of the plurality of data sets.

10. A computerized method comprising:
inputting, by a processor, input data representing a state of an electronically controlled suspension (ECS) system into an artificial neural network model and obtaining, by the processor, an estimated value of a physical quantity representing an output of the ECS system from the artificial neural network model; and
detecting abnormality of a solenoid valve included in the ECS system of a vehicle by comparing, by the processor, the estimated value of the physical quantity obtained from the artificial neural network model with a measured value of the physical quantity measured by one or more sensors.

11. The method of claim 10, wherein the input data comprises one or more signals obtained through a controller area network (CAN) of the vehicle.

12. The method of claim 10, wherein the physical quantity includes a damping force of the ECS system.

13. The method of claim 10, wherein the input data includes a vertical acceleration of a wheel of the vehicle and a vertical acceleration of a body of the vehicle.

14. The method of claim 13, wherein the input data further includes at least one of a speed of the wheel of the vehicle, a steering angle of the vehicle, a steering angular velocity of the vehicle, a displacement of an accelerator pedal of the vehicle, a displacement of a brake pedal of the vehicle, and a lateral acceleration of the vehicle.

15. The method of claim 10, wherein the artificial neural network model includes a generative adversarial network (GAN) including a generator configured to receive the input data representing the state of the ESC system and generate the estimated value based on the received input data, and a discriminator configured to receive measurement data including the input data representing the state of the ESC system and the measured value of the physical quantity measured by the one or more sensors and output a discrimination value for the measurement data.

16. The method of claim 15, wherein the detecting of the abnormality of the solenoid valve includes:
inputting, by the processor, the measurement data including the input data representing the state of the ESC system and the measured value of the physical quantity measured by the one or more sensors into the discriminator and obtaining the discrimination value for the measurement data generated by the discriminator; and
inputting, by the processor, error data including the discrimination value for the measurement data and a value related to a difference between the estimated value of the physical quantity obtained from the artificial neural network model and the measured value of the physical quantity measured by the one or more sensors into an abnormality detection model to determine whether the solenoid valve included in the ECS system is abnormal based on an output of the abnormality detection model.

17. A non-transitory computer-readable medium configured to store at least one instruction, that when executed by a processor, cause the processor to perform operations comprising:
inputting input data representing a state of an electronically controlled suspension (ECS) system into an artificial neural network model,
obtaining at least one estimated value of a physical quantity representing an output of the ECS system from the artificial neural network model,
detecting abnormality of a solenoid valve included in the ECS system of a vehicle by comparing the at least one estimated value of the physical quantity obtained from the artificial neural network model with at least one measured value of the physical quantity measured by one or more sensors.
